(19) United States
(12) Patent Application Publication
(10) Pub. No.: US 2011/0226971 A1
(43) Pub. Date: Sep. 22, 2011

(54) DETECTING DEVICE

(76) Inventor: Jen-Gwo SUN, Hsinchu (TW)

(21) Appl. No.: 12/725,833

(22) Filed: Mar. 17, 2010

(51) Int. Cl. H01L 31/12; H01L 31/09; H01L 31/02; H01L 31/113

(52) U.S. Cl. 250/552; 250/214 R; 250/214.1

(57) ABSTRACT

A detecting device is provided, which collocates with an electronic device to constitute a diagnostic system. The detecting device comprises a main-body, a carrier, an image sensor, a controller and a transmission interface. The carrier is disposed within the main-body for carrying a specimen. The image sensor is disposed within the main-body for detecting the specimen and generating a sensor signal. The controller is electrically connected with the image sensor for processing the sensor signal into an image signal. The transmission interface is electrically connected with the controller and the image signal is transmitted to the electronic device via the transmission interface.

### BACKGROUND OF THE INVENTION

1. Field of the Invention

The present invention relates to a detecting device, and more particularly to specimen detecting device.

2. Description of the Prior Art

Inspecting biological samples of patients (e.g. urine, body fluid, excrement and etc.) in a hospital usually takes hours, even few days, to get a diagnostic report. Besides, conventional diagnostic devices are too expensive for most people to be promoted to family. Although there are reagent test strips available for patients to perform self-inspections, patients who are lack of professional knowledge are not capable of recognizing results shown on the test strips.

### SUMMARY OF THE INVENTION

The present invention is directed to provide a detecting device which collocates with an electronic device to constitute a diagnostic system. The electronic device, which had been available in family, is responsible for analyzing, recording and managing signals transmitted from the detecting device according to the present invention. Therefore, the components of the detecting device are simplified thereby lowering the manufacturing cost.

In one embodiment, the proposed detecting device comprises a main-body, a carrier, an image sensor, a controller and a transmission interface. The carrier is disposed within the main-body and configured for carrying a specimen. The image sensor is disposed within the main-body for detecting the specimen and generating a sensor signal. The controller is electrically connected with the image sensor and configured for processing the sensor signal into an image signal. The transmission interface is electrically connected with the controller, wherein the image signal is transmitted to an electronic device via the transmission interface.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is an explosion diagram schematically illustrating an embodiment of the detecting device according to the present invention;

FIG. 2 is a schematic diagram illustrating a diagnostic system comprising an embodiment of the detecting device according to the present invention and an electronic device;

FIG. 3 is an explosion diagram schematically illustrating another embodiment of the detecting device according to the present invention; and

FIG. 4 is a schematic diagram illustrating a lens of another embodiment of the detecting device according to the present invention focusing a light.

### DESCRIPTION OF THE PREFERRED EMBODIMENT

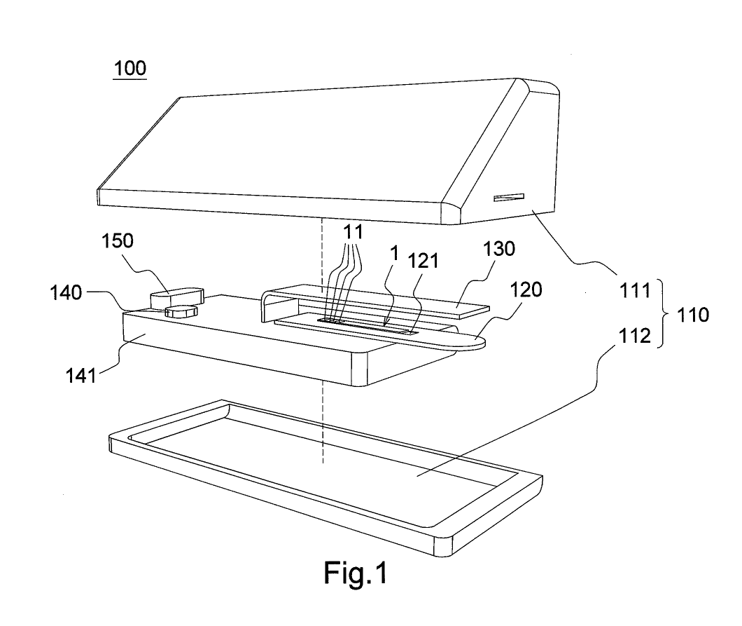

FIG. 1 is an explosion diagram illustrating an embodiment of the detecting device 100 according to the present invention. The detecting device 100 comprises a main-body 110, a carrier 120, an image sensor 130, a controller 140 and a transmission interface 150. The main-body 110 comprising an upper cap 111 and a bottom cover 112 can be but not limited to be combined with rabbeting or screwing; alternatively, the main-body 110 may also be formed integrally. The carrier 120 is disposed within the main-body 110 and configured for carrying a specimen 1. The carrier 120 is movable with respect to the main-body 110 for loading or removing the specimen 1 by moving the carrier 120.

The carrier 120 of the detecting device 100 further comprises a concave portion 121 for holding the specimen 1 at a predetermined position. The specimen 1 can be, but not limited to be, a liquid or a test strip. In this embodiment according to the present invention, the specimen 1 may be a test strip comprising a plurality of test areas 11 and each test area 11 may preferably have different kinds of reactants. For example, the specimen (test strip) 1 may be a urine test strip and each test area 11 is capable of undergoing a color change in response to contact with a urine. The urine usually contains one or more constituents. The presence and concentrations of these constituents are determinable by an analysis of the color changes undergone by the test areas 11 of the test strip 1.

The image sensor 130 is disposed within the main-body 110 and configured for detecting the image of the specimen 1 and generating a sensor signal. The image sensor 130 may be a charge-coupled device (CCD) sensor or a complementary metal-oxide-semiconductor (CMOS) sensor. In this embodiment according to the present invention, the image sensor 130 can, but not limited to, comprise a CCD sensor. A light source (not shown) provides light to illuminate the specimen 1 for the image sensor 130 to receive the light reflected from the specimen 1 to generate the sensor signal. It should be noted that the light source (not shown) can be, but not limited to be, disposed within the main-body 110. In one embodiment, the light source (not shown) may be a light-emitting diode (LED) or a cold cathode fluorescent lamp (CCFL).

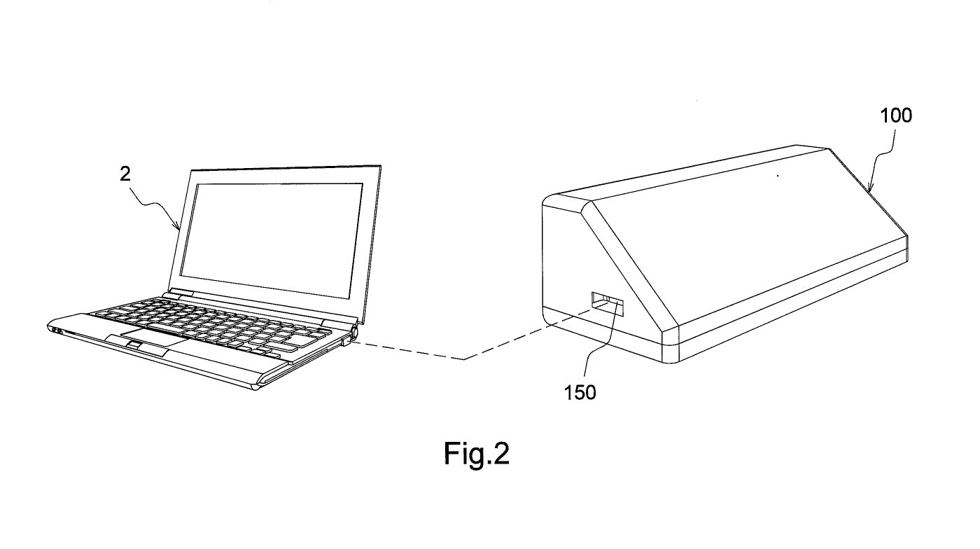

The controller 140 is electrically connected with the image sensor 130 via a printed circuit board 141 and configured for processing the sensor signal into an image signal. The image sensor 130 is capable of generating individual sensor signal corresponding to color change on each test area 11. It is understood that if the specimen 1 is a liquid, the color of the liquid may also be sensed by the image sensor 130. The transmission interface 150 is electrically connected with the controller 140 via the printed circuit board 141. The transmission interface 150 may be a RS232 interface, an IEEE 1394 interface, a Bluetooth interface, an infrared transmission interface, a USB interface or any combination thereof. As shown in FIG. 2, the detecting device 100 collocates with an electronic device 2 (e.g. a computer) to constitute a diagnostic system. The detecting device 100 transmits the image signal to the electronic device 2 via the transmission interface 150 for analyzing, recording and managing the image signal. A specific software installed in the electronic device 2 is capable of processing the image signal and analyzing the presence and concentrations of constituents in the specimen 1 (shown in FIG. 1), such as glycosuria, ketone body, urinary protein, occult blood, nitrite, bilirubin, urobilinogen, specific weight or white corpuscle.

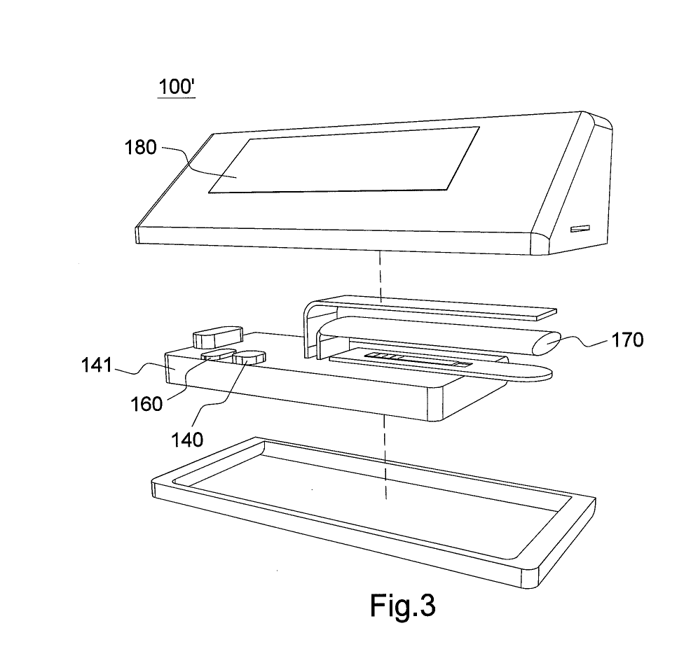

FIG. 3 is an explosion diagram illustrating another embodiment of the detecting device 100′ according to the present invention. The detecting device 100′ further comprises a storage unit 160 electrically connected with the controller 140 via the printed circuit board 141 for storing the image signal in file format. The storage unit 160 may be a hard drive or a memory. The electronic device 2 (shown in FIG. 2) is capable of processing the image signal by accessing the file stored in the storage unit 160 without detecting the specimen 1 simultaneously, thereby increasing the usage efficiency of the detecting device. Besides, the storage unit 160 is capable of storing plurality of files, thereby achieving self-health management. In another embodiment, the detecting device further comprises an external storage interface electrically connected with the controller via the printed circuit board. The external storage interface may be a USB interface or a memory card interface. The image file stored in the storage unit 160 is transmitted to a USB flash memory or a memory card via the external storage interface.

It should be noted that the storage unit 160 further comprises a standard sensor signal, which is the sensor signal of a standard specimen. Calibration of the detecting device 100, 100′ is achieved by storing a calibration value in the storage unit 160. The calibration value is produced by the controller 140 by comparing the sensor signal of the standard specimen generated by the image sensor 130 (denoted in FIG. 1) with the standard sensor signal, when the standard specimen is disposed on the carrier 120 (denoted in FIG. 1). The controller 140 may then generate a calibrated image signal after the calibration value is considered thereby achieving precise detection.

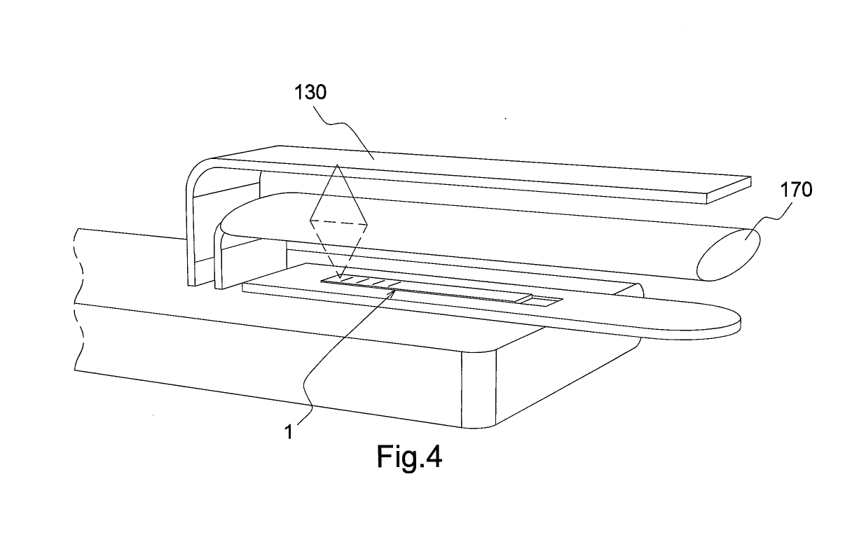

Referring to FIG. 4, the detecting device 100′ (denoted in FIG. 3) further comprises at least one lens 170 disposed between the image sensor 130 and the carrier 120 (denoted in FIG. 1) and configured for focusing the image of the specimen 1 on the image sensor 130 thereby improving the image quality. The lens 170 may be an elongated structure or a microlens array. As shown in FIG. 3, the detecting device 100′ further comprises a display unit 180 (e.g. a liquid crystal display) disposed on the main-body 110 (denoted in FIG. 1) and electrically connected to the controller 140 for displaying information about the status of the detecting device 100′.

Another embodiment according to the present invention further comprises a drive motor disposed in the carrier and configured for driving the carrier to move with respect to the image sensor so as to scan the specimen; alternatively, the drive motor may be disposed in the image sensor and configured for driving the image sensor to move with respect to the carrier so as to scan the specimen, thereby forming a full color image of the specimen for measuring the chromaticity and inspecting impurities of the specimen.

In summary, the detecting device according to the present invention collocates with an electronic device to constitute a diagnostic system. The image sensor (such as a CCD sensor) of the detecting device is configured for detecting the specimen. The components of the detecting device are simplified because the electronic device, which had been available at home, is responsible for analyzing, recording and managing signals transmitted from the detecting device, thereby lowering the manufacture cost and being affordable for family.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A detecting device, collocating with an electronic device to constitute a diagnostic system, wherein said detecting device comprises:
a main-body;
a carrier disposed within said main-body and configured for carrying a specimen;
an image sensor disposed within said main-body and configured for detecting said specimen and generating a sensor signal;
a controller electrically connected with said image sensor and configured for processing said sensor signal into an image signal; and
a transmission interface electrically connected with said controller, wherein said image signal is transmitted to said electronic device via said transmission interface.

2. The detecting device according to claim 1, wherein said carrier is movable with respect to said main-body.

3. The detecting device according to claim 1, wherein said image sensor comprises a charge coupled device (CCD) sensor or a complementary metal-oxide-semiconductor (CMOS) sensor.

4. The detecting device according to claim 1, wherein said transmission interface comprises a RS232 interface, an IEEE 1394 interface, a Bluetooth interface, an infrared transmission interface, a USB interface or any combination thereof.

5. The detecting device according to claim 1, further comprising:
at least one lens disposed between said image sensor and said carrier and configured for focusing an image of said specimen onto said image sensor.

6. The detecting device according to claim 5, wherein said lens comprises an elongated structure.

7. The detecting device according to claim 5, wherein said lens comprises a microlens array.

8. The detecting device according to claim 1, further comprising:
a light source disposed within said main-body and configured for providing light to illuminate said specimen.

9. The detecting device according to claim 8, wherein said light source comprises a light-emitting diode (LED) or a cold cathode fluorescent lamp.

10. The detecting device according to claim 1, further comprising:
a storage unit electrically connected with said controller and configured for storing said image signal in file format.

11. The detecting device according to claim 10, wherein said storage unit comprises a hard drive, a memory or any combination thereof.

12. The detecting device according to claim 10, further comprising an external storage interface electrically connected with said controller.

13. The detecting device according to claim 1, further comprising a display unit electrically connected to said controller and configured for displaying information about the status of said detecting device.

14. The detecting device according to claim 13, wherein said display unit comprises a liquid crystal display.

15. The detecting device according to claim 1, further comprising:
a drive motor disposed in said carrier and configured for driving said carrier to move with respect to said image sensor so as to scan said specimen.

16. The detecting device according to claim 1, further comprising:
a drive motor disposed in said image sensor and configured for driving said image sensor to move with respect to said carrier so as to scan said specimen.

17. The detecting device according to claim 1, wherein said main-body comprises an upper cap and a bottom cover combined together.

18. The detecting device according to claim 1, wherein said carrier further comprises a concave portion configured for holding said specimen at a predetermined position.
